(19) United States
(12) Patent Application Publication
(10) Pub. No.: US 2026/0312739 A1
(43) Pub. Date: Oct. 8, 2026

(54) CALIBRATION CIRCUIT, CALIBRATION METHOD, EXTERNAL SIGNAL INTERFACE CHIP, AND ELECTRONIC APPARATUS

(71) Applicant: INNOGRIT TECHNOLOGIES CO., LTD., Shanghai (CN)

(72) Inventors: Xiuli XU, Shanghai (CN); Nannan YU, Shanghai (CN); Lei JIANG, Shanghai (CN); Yongxu WANG, Shanghai (CN)

(21) Appl. No.: 19/638,230

(22) Filed: Apr. 3, 2026

(30) Foreign Application Priority Data
Apr. 7, 2025 (CN) 202510424550.4

(51) Int. Cl. H04L 1/20; H04L 25/03

(52) U.S. Cl. CPC H04L 1/206; H04L 1/203; H04L 25/03885; H04L 1/205

(57) ABSTRACT

The present disclosure relates to a calibration circuit, a calibration method, an external signal interface chip, and an electronic apparatus. A calibration circuit comprises a reference voltage modulation part and a delay part, a first terminal of the reference voltage modulation part is connected to a first connection point, a second terminal of the reference voltage modulation part is connected to a second connection point, and the reference voltage modulation part is configured to calibrate a reference voltage of an external signal interface chip; an input terminal of the delay part is configured to receive a sampling clock signal, an output terminal of the delay part is connected to a control terminal of a comparator, and the delay part is configured to calibrate the sampling clock signal of the external signal interface chip.

### RELATED MATTERS

This application claims priority to Chinese Patent Application No. 202510424550.4, filed 5 on Apr. 7, 2025 and published as Chinese Patent Publication No. 120377909 A, the contents of which are hereby incorporated by reference in their entirety.

### TECHNICAL FIELD

The present disclosure relates to the field of electronic technologies, and in particular, to a calibration circuit, a calibration method, an external signal interface chip, and an electronic apparatus.

### BACKGROUND

With the development of high-rate communication systems, external signal interface chips (also called PHY, Physical Layer) are widely used in various memory chips, for example, a fifth-generation double data rate synchronous dynamic random access memory (Double Data Rate SDRAM, DDR5), a fifth-generation low power double data rate dynamic random access memory (Low Power Double Data Rate SDRAM, LPDDR5), and a flash memory (NAND). Compared with the fifth-generation memory chip, the data transmission rate of the fourth-generation memory chip is only required to reach 3200 MT/s or 4266 MT/s at most, the data transmission rate of the fourth-generation memory chip is approximately half of that of the fifth-generation memory chip, the design of the receiving circuit in the fourth-generation memory chip usually adopts a static comparator, and the advantages of the static comparator are simple structure design, low circuit timing requirements, and linear amplification of the data signal by the static comparator. However, the static comparator has low efficiency in optimizing the jitter of the data eye diagram, and in order to pursue bandwidth requirements, the static power consumption of the circuit is relatively large. In view of this, a receiving circuit of the fifth-generation memory chip adopts a dynamic comparator, the dynamic comparator may be applicable to a high-speed input/output communication system, and static power consumption of the dynamic comparator is relatively low. However, a disadvantage of the dynamic comparator is that the dynamic comparator is relatively sensitive to noise and deviation, and in addition, the dynamic comparator needs a sampling clock, which has a relatively high requirement on a timing sequence of a circuit.

Further, for the design of an external signal interface chip in the related art, eight or more groups of data signal line ports are often adopted in the chip to read and write data at the same time, and reference voltages for comparison are connected to a plurality of data signal line ports at the same time. Because of the deviation among the data signal line ports, the same reference voltage is not suitable for each data signal line port, so the output signal amplitude of the receiving circuit of the data signal line port is reduced and the eye height of the eye diagram is deteriorated. If a dynamic comparator is adopted in the receiving circuit of the input/output port (IO), a sampling clock of the dynamic comparator is also connected to a plurality of data signal line ports, and due to layout and wiring of the layout, it cannot be ensured that sampling edges in all data signal line ports are consistent. When the data transmission rate is relatively low, there is sufficient margin for both the height and width of the data eye diagram itself for sampling, but for a communication scenario with a relatively high data transmission rate, it is very important to calibrate the reference voltage and the sampling clock for comparison with the data signal.

### SUMMARY

In view of this, the present disclosure provides a calibration circuit, a calibration method, an external signal interface chip, and an electronic apparatus.

According to an aspect of the present disclosure, a calibration circuit is provided, the calibration circuit is applied to an external signal interface chip, a receiving circuit of the external signal interface chip comprises an amplifier and a comparator, an inverting input terminal of the amplifier is configured to receive a reference voltage, a non-inverting input terminal of the amplifier is configured to receive an external data signal, a non-inverting output terminal of the amplifier is connected to a non-inverting input terminal of the comparator at a first connection point, and an inverting output terminal of the amplifier is connected to an inverting input terminal of the comparator at a second connection point; the calibration circuit comprises a reference voltage modulation part and a delay part, a first terminal of the reference voltage modulation part is connected to the first connection point, a second terminal of the reference voltage modulation part is connected to the second connection point, and the reference voltage modulation part is configured to calibrate the reference voltage of the external signal interface chip; an input terminal of the delay part is configured to receive a sampling clock signal, an output terminal of the delay part is connected to a control terminal of the comparator, and the delay part is configured to calibrate the sampling clock signal of the external signal interface chip.

In a possible implementation, the performing calibration based on the calibration circuit comprises: acquiring an eye diagram of the data signal based on the first connection point and the second connection point; adjusting a reference voltage modulation part of the calibration circuit to calibrate the reference voltage, to maximize an eye width of the eye diagram; and/or adjusting a delay part of the calibration circuit to calibrate the sampling clock signal, to enable the comparator to sample a position with a maximum eye height in the eye diagram.

In a possible implementation, the reference voltage modulation part comprises an adjustable current source, a first transistor, and a second transistor, a first terminal of the adjustable current source is configured to receive a power signal, a second terminal of the adjustable current source is connected to a first terminal of the first transistor and a first terminal of the second transistor, a second terminal of the first transistor is connected to the first connection point, a second terminal of the second transistor is connected to the second connection point, a control terminal of the first transistor is configured to receive a first control signal, a control terminal of the second transistor is configured to receive a second control signal, the first control signal and the second control signal are configured to modulate the reference voltage, and the adjustable current source is configured to determine a modulation range of the reference voltage.

In a possible implementation, the voltage at the first connection point is increased in response to the first transistor being turned on by the first control signal and the second transistor being turned off by the second control signal; and the voltage at the second connection point is increased in response to the first transistor being turned off by the first control signal and the second transistor being turned on by the second control signal.

In a possible implementation, the reference voltage modulation part comprises a current source, a third transistor, and a fourth transistor, a first terminal of the current source is configured to receive a power signal, a second terminal of the current source is connected to a first terminal of the third transistor and a first terminal of the fourth transistor, a second terminal of the third transistor is connected to the first connection point, a second terminal of the fourth transistor is connected to the second connection point, a control terminal of the third transistor is configured to receive the data signal, a control terminal of the fourth transistor is configured to receive the reference voltage, and the reference voltage is modulated by changing sizes of the third transistor and the fourth transistor.

In a possible implementation, the reference voltage modulation part comprises a first adjustable resistor and a second adjustable resistor, a first terminal of the first adjustable resistor is connected to the first connection point, a first terminal of the second adjustable resistor is connected to the second connection point, a second terminal of the first adjustable resistor and a second terminal of the second adjustable resistor are grounded, and the reference voltage is modulated by changing resistance values of the first adjustable resistor and the second adjustable resistor.

In a possible implementation, the delay part comprises a plurality of buffers sequentially connected in series and a one-out-of-multiple selector, wherein an input terminal of a first buffer in the plurality of buffers sequentially connected in series is used as the input terminal of the delay part to receive the sampling clock signal, output terminals of the plurality of buffers are respectively connected to a plurality of input terminals of the one-out-of-multiple selector, and an output terminal of the one-out-of-multiple selector is used as the output terminal of the delay part to be connected to the control terminal of the comparator.

According to another aspect of the present disclosure, an external signal interface chip is provided, the external signal interface chip comprises a plurality of receiving circuits, the plurality of receiving circuits share a same reference voltage, and each receiving circuit is respectively connected to one calibration circuit as described above.

According to another aspect of the present disclosure, there is provided a calibration method applied to the calibration circuit as described above, the method comprises: acquiring an eye diagram of the data signal based on the first connection point and the second connection point; adjusting a reference voltage modulation part of the calibration circuit to calibrate the reference voltage to maximize an eye width of the eye diagram; and/or adjusting a delay part of the calibration circuit to calibrate the sampling clock signal to enable the comparator to sample a position with a maximum eye height in the eye diagram.

According to another aspect of the present disclosure, there is provided an electronic apparatus including the calibration circuit as described above.

According to another aspect of the present disclosure, there is provided a chip including the calibration circuit as described above.

The calibration circuit of the embodiment of the present disclosure comprises a reference voltage modulation part and a delay part, the reference voltage modulation part is configured to calibrate a reference voltage of the external signal interface chip, and the delay part is configured to calibrate a sampling clock signal of the external signal interface chip. The calibration circuit according to the embodiment of the present disclosure can effectively calibrate the reference voltage and the sampling clock signal of the external signal interface chip to ensure the stability of data transmission and improve the accuracy and reliability of the external signal interface chip.

Other features and aspects of the present disclosure will become apparent from the following detailed description of exemplary embodiments with reference to the accompanying drawings.

### BRIEF DESCRIPTION OF THE DRAWINGS

The accompanying drawings, which are incorporated in and constitute a part of this specification, illustrate exemplary embodiments, features, and aspects of the present disclosure and, together with the description, serve to explain the principles of the disclosure.

FIG. 1 shows a schematic diagram of an eye diagram according to an embodiment of the disclosure.

FIG. 2 shows a schematic circuit diagram of an external signal interface chip in the related art.

FIG. 3 shows a schematic diagram of a data signal line port in the related art.

FIG. 4 shows a schematic diagram of a calibration circuit according to an embodiment of the disclosure.

FIG. 5 shows a schematic circuit diagram of a reference voltage modulation part according to an embodiment of the disclosure.

FIG. 6 shows a schematic circuit diagram of a reference voltage modulation part according to another embodiment of the present disclosure.

FIG. 7 shows a schematic circuit diagram of a reference voltage modulation part according to another embodiment of the present disclosure.

FIG. 8 shows a schematic circuit diagram of a delay part according to an embodiment of the present disclosure.

FIG. 9 shows a schematic circuit diagram of an external signal interface chip according to an embodiment of the present disclosure.

FIG. 10 shows a flowchart of a calibration method according to an embodiment of the present disclosure.

### DETAILED DESCRIPTION

Various exemplary embodiments, features and aspects of the present disclosure will be described in detail below with reference to the accompanying drawings. The same reference numbers in the drawings indicate functionally the same or similar elements. While the various aspects of the embodiments are presented in drawings, the drawings are not necessarily drawn to scale unless specifically indicated.

As used herein, the terms “comprising”, “containing”, “having,” or variants thereof are open-ended and include one or more stated features, integers, elements, steps, components, or functions but do not preclude the presence or addition of one or more other features, integers, elements, steps, components, functions, or groups thereof.

When an element is referred to as being “connected”, “coupled”, “responsive”, or variants thereof to another element, it can be directly connected, coupled, or responsive to the other element or intervening elements may be present.

Although the terms first, second, third, etc. may be used herein to describe various elements/operations, these elements/operations should not be limited by these terms. These terms are only used to distinguish one element/operation from another element/operation. Thus, a first element/operation in some embodiments could be termed a second element/operation in other embodiments without departing from the teachings of the inventive concept.

The word “exemplary” is used exclusively herein to mean “serving as an example, embodiment, or illustration.” Any embodiment described herein as “exemplary” is not necessarily to be construed as preferred or advantageous over other embodiments.

In addition, in order to better illustrate the present disclosure, numerous specific details are given in the following specific embodiments. It will be understood by those skilled in the art that the present disclosure may be practiced without some of the specific details. In some instances, methods, means, elements, and circuits well known to those skilled in the art are not described in detail, so as to highlight the subject matter of the present disclosure.

In order to facilitate the understanding of the technical solutions of the present disclosure, professional names or terms involved below are first explained and described herein.

An eye diagram is an image formed by overlapping waveforms of each symbol obtained through scanning through a persistence effect of an oscilloscope, and is used to evaluate integrity of a data signal. As a result of accumulating, superimposing, and displaying the bits of the serial signal in a persistence manner, the superimposed graphic shape looks very similar to the eye, so the eye diagram is named.

FIG. 1 shows a schematic diagram of an eye diagram according to an embodiment of the present disclosure, as shown in FIG. 1, an eye height represents a maximum opening height of the eye diagram in a vertical direction (amplitude axis), and an eye width refers to a maximum opening width of the eye diagram in a horizontal direction (time axis), that is, an effective time window of a signal at an optimal sampling point. The eye diagram contains rich information, and the influence of inter-symbol crosstalk and noise can be observed from the eye diagram, which reflects the overall characteristics of the digital signal, so that the quality of the communication system can be estimated, for example, the transmission signal of the high-speed interconnection system can be analyzed. In addition, the diagram may also be used to adjust the communication system to reduce inter-symbol crosstalk and improve the transmission performance of the communication system.

The external signal interface chip (PHY) may also be referred to as a port physical layer, and is a chip that interfaces with an external signal.

For example, in the related art, for the external signal interface chip integrated with the fourth-generation memory chip, the working manual thereof sets the power supply voltage VDDQ (for example, 1.2V or 1.1V), the voltage range of the data signal is relatively high (for example, 0.5*VDDQ to VDDQ or 0 to 0.5*VDDQ) due to the influence of system terminal impedance matching, and the data transmission rate is not very high (for example, 3200 MT/s or 4266 MT/s), the data signal passes through the transmission line and is connected to the input terminals of the receiving circuits of the plurality of data signal line ports in the external signal interface chip, since the height and width of the data eye diagram have sufficient margin, it means that the signal has sufficient space and tolerance to cope with various interferences and changes in the current signal transmission environment, so the plurality of data signal line ports can use the same reference voltage, if the receiving circuit adopts the dual-edge sampling mode of sampling by dynamic comparator, in the case where the sampling rate is not very high (for example, 1.6GHz or 2.4GHz), it can be supported that the plurality of receiving circuits adopt the same sampling clock, and the bit error rate of data transmission will not increase.

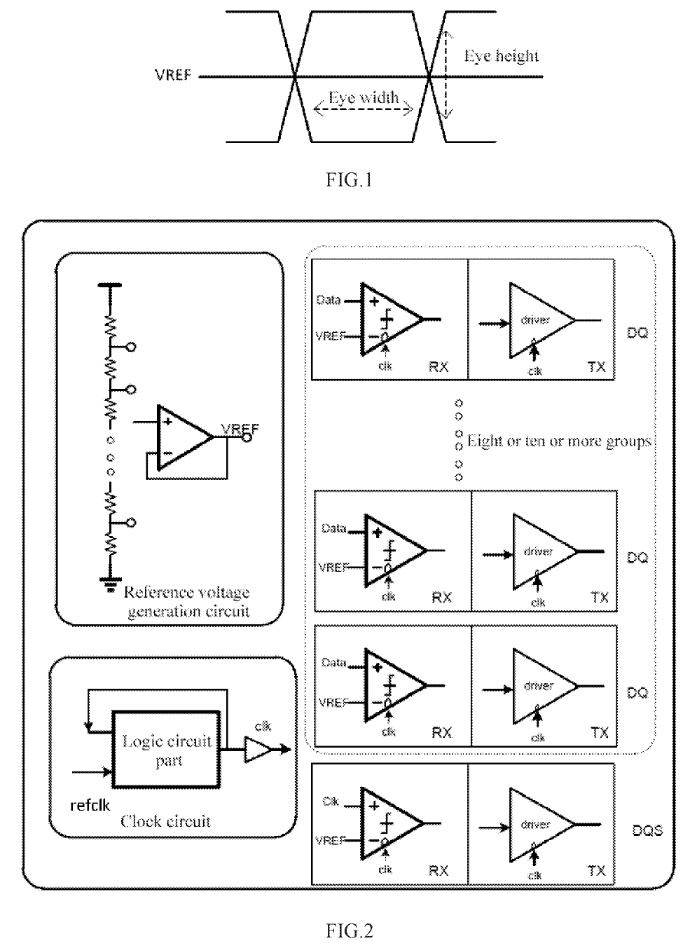

FIG. 2 shows a schematic circuit diagram of an external signal interface chip in the related art. As shown in FIG. 2, the external signal interface chip may include a reference voltage generation circuit, a clock circuit, a plurality of data signal line ports DQ, and a clock signal line port DQS.

The reference voltage generation circuit comprises a plurality of resistors and an operational amplifier connected in series, the plurality of resistors are provided for voltage-dividing the power supply to provide a plurality of voltage division nodes (for example, connection points of any two adjacent resistors), a non-inverting input terminal of the operational amplifier is selectively connected to a certain voltage division node, and an inverting input terminal of the operational amplifier is connected to an output terminal of the operational amplifier, and is configured to provide a reference voltage VREF for the receiving circuit RX in the data signal line port DQ.

The clock circuit comprises a logic circuit part and a buffer, where an output terminal, a first input terminal of the logic circuit part, and an input terminal of the buffer are connected to each other, a second input terminal of the logic circuit part is configured to receive a reference clock refclk, and an output terminal of the buffer serves as an output terminal of the clock circuit and is configured to provide a sampling clock signal clk for each data signal line port DQ and clock signal line port DQS.

Optionally, the logic circuit part may comprise a Phase-Locked Loop (PLL), a Phase Interpolator (PI), and a Duty Cycle Corrector (DCC), and generate a clock signal through mutual cooperation. For example, the phase-locked loop may generate a preliminary clock signal according to the reference clock refclk, and use a phase interpolator and a duty cycle corrector to adjust the frequency and phase of the clock signal through a feedback mechanism. The phase interpolator may adjust a phase of the clock signal, and the duty cycle corrector may adjust a duty cycle of the clock signal. In this way, the logic circuit part generates a sampling clock signal clk that can control the phase.

The data signal line port DQ and the clock signal line port DQS are unit circuits involving read and write signals in the external signal interface chip, each of the data signal line port DQ and the clock signal line port DQS comprises a transmitting circuit TX and a receiving circuit RX, and a plurality of data signal line ports DQ operate simultaneously as a group. The transmitting circuit TX comprises a buffer driver, and the buffer driver is configured to transmit an internal signal to an external part based on an indication of the sampling clock signal clk. The receiving circuit RX may comprise a comparator, a first input terminal of the comparator is configured to receive an external data signal Data (or a sampling clock signal clk), a second input terminal of the comparator is configured to receive a reference voltage VREF, a control terminal of the comparator is configured to receive the sampling clock signal clk, and an output terminal of the comparator is configured to provide a sampled and compared input signal for an internal System on Chip (SoC).

However, the external signal interface chip shown in FIG. 2 cannot meet a memory chip with a higher transmission rate, for example, a fifth-generation double data rate synchronous dynamic random access memory (DDR5), a fifth-generation low power double rate dynamic random access memory (Low Power Double Data Rate SDRAM, LPDDR5), or a flash (NAND). For an external signal interface chip used by a memory chip with a higher transmission rate, a data transmission rate of the memory chip increases exponentially, and a signal that arrives at a data signal line port DQ through a channel also decays exponentially with a frequency. The rate of the sampling clock is multiplied. In addition, due to factors such as inter-symbol interference and crosstalk, both an eye height and an eye width of an eye diagram of a data signal received by the receiving circuit RX decrease, and a bit error rate of sampling also increases exponentially. Therefore, the reference voltage and the sampling clock of the data signal line port DQ suitable for the fourth-generation memory chip need to be optimized to support data signals with higher transmission rates.

For a higher-speed fifth-generation memory chip, an external signal interface chip adopted by the higher-speed fifth-generation memory chip may also include a plurality of data signal line ports DQ and one clock signal line port DQS, the data signal line port DQ is configured to read and write data information, and the clock signal line port DQS is configured to read and write a sampling clock signal. The data signal line ports DQ may be grouped in eight or ten or even more numbers.

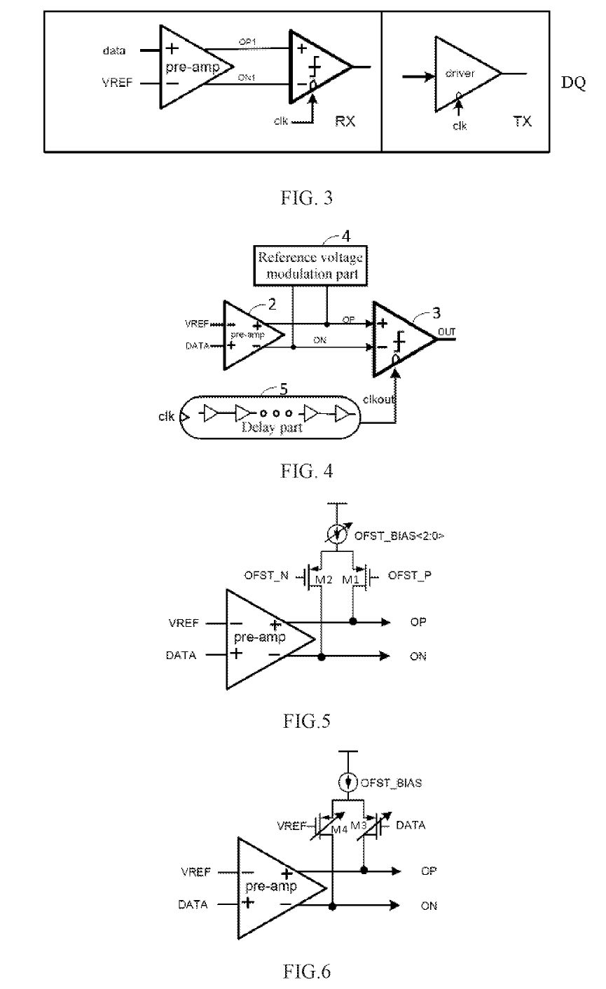

FIG. 3 shows a schematic diagram of a data signal line port in the related art. As shown in FIG. 3, each data signal line port DQ may include a receiving circuit RX and a transmitting circuit TX. The receiving circuit RX is configured to read data information, and may include a comparator. In order to support higher data transmission rate (for example, the data rate is 6400 MT/s), dynamic comparator can be selected for sampling. For example, the receiving circuit RX may include a pre-amplifier pre-amp and a dynamic sampling comparator, an inverting input terminal of the pre-amplifier pre-amp is configured to receive the reference voltage VREF, a non-inverting input terminal of the pre-amplifier pre-amp is configured to receive an external data signal data, a non-inverting output terminal of the pre-amplifier pre-amp is connected to a non-inverting input terminal of the dynamic sampling comparator at a connection point OP1, an inverting output terminal of the pre-amplifier pre-amp is connected to an inverting input terminal of the dynamic sampling comparator at a connection point ON1, and a control terminal of the dynamic sampling comparator is configured to receive the sampling clock signal clk. The pre-amplifier pre-amp may include a linear equalization circuit and a feedback equalization circuit, both of which can amplify the data signal data and output it to the sampling comparator for sampling. The transmitting circuit TX can be referred to above and will not be described here.

For a communication system with a higher transmission rate, taking the fifth-generation low power double data rate dynamic random access memory (LPDDR5) as an example, its data signal voltage range is 0 to 0.5 V, and the data rate is supported to 6400 MT/s. In order to adapt to high-speed data transmission, the requirements of the receiving circuit RX in the data signal line port for the data eye diagram are as follows: when the power supply voltage VDDQ for supplying power to the input/output port buffer is set to 0.5V and the data rate reaches 6400 MT/s, the pulse response width of the receiving circuit RX of the data signal line port reaches 0.45 Unit Interval (UI), and the pulse signal response amplitude thereof reaches +/-70mV.

Therefore, the high-speed external signal interface chip is designed, and the receiving circuit RX is required to amplify the received data eye diagram amplitude, optimize the eye diagram jitter, perform sampling comparison, and then transmit it to the System on Chip. In this process, for a linearly amplified eye diagram, how to ensure that a sampling clock of a dynamic sampling comparator can acquire a maximum amplitude of the eye diagram, and how to set a reference voltage used for sampling can ensure that an eye width of the eye diagram reaches a maximum value are one of design difficulties of a communications system in a high-speed memory chip. The key point of another design is that when the communication system works normally, for the communication at the physical level, because the reference voltage of each data signal line port of the external signal interface chip comes from the same circuit, so how to adapt to each data signal line port is also one of the difficulties, that is, how to use an adopted clock to adapt to each data signal line port to ensure that the rising edge or falling edge of the clock can be aligned with the highest amplitude of each eye diagram during sampling.

In view of this, embodiments of the present disclosure provide a calibration circuit for calibrating a reference voltage and a sampling clock signal of an external signal interface chip to ensure stability of data transmission and improve accuracy and reliability of the external signal interface chip.

FIG. 4 shows a schematic diagram of a calibration circuit according to an embodiment of the disclosure. As shown in FIG. 4, the calibration circuit is applied to an external signal interface chip, a receiving circuit in a data signal line port DQ of the external signal interface chip comprises an amplifier 2 and a comparator 3, the data signal line port DQ is not shown in FIG. 4, FIG. 3 may be referred to for the exemplary structure of the data signal line port DQ, and the present application does not limit the specific structure of the data signal line port DQ. An inverting input terminal of the amplifier 2 is configured to receive a reference voltage VREF, a non-inverting input terminal of the amplifier 2 is configured to receive an external data signal DATA, a non-inverting output terminal of the amplifier 2 is connected to a non-inverting input terminal of the comparator 3 at a first connection point OP, and an inverting output terminal of the amplifier 2 is connected to an inverting input terminal of the comparator 3 at a second connection point ON.

FIG. 3 may be referred to for exemplary descriptions of the amplifier 2 and the comparator 3, and the specific structures of the amplifier 2 and the comparator 3 are not limited in the application. The reference voltage VREF of the external signal interface chip may be generated by, for example, the reference voltage generation circuit shown in FIG. 2 or other optional reference voltage generation circuits, and sent to the inverting input terminal of the amplifier 2 in the receiving circuit. For example, assuming that the power supply voltage VDDQ is 0.5 V, the voltage range of the data signal DATA is 0 to 0.5×VDDQ, and the default value of the reference voltage VREF is 0.25×VDDQ, the reference voltage generation circuit may be used to set the reference voltage VREF to 0.25×VDDQ. The embodiments of the present disclosure do not limit the specific value of the reference voltage VREF.

The calibration circuit comprises a reference voltage modulation part 4 and a delay part 5, where a first terminal of the reference voltage modulation part 4 is connected to the first connection point OP, a second terminal of the reference voltage modulation part 4 is connected to the second connection point ON, and the reference voltage modulation part 4 is configured to calibrate a reference voltage VREF of the external signal interface chip, so that an eye width of an eye diagram (that is, eye diagrams collected from the first connection point OP and the second connection point ON) collected by an input terminal of the comparator 3 is the largest, and after eye diagrams are sampled and compared by the comparator 3, a signal OUT is output to an internal System on Chip.

An input terminal of the delay part 5 is configured to receive the sampling clock signal clk, an output terminal of the delay part 5 is connected to a control terminal of the comparator 3, and the delay part 5 is configured to calibrate the sampling clock signal clk of the external signal interface chip and send the calibrated sampling clock signal clkout to the control terminal of the comparator 3.

It should be noted that although the calibration circuit is described above by taking FIG. 4 as an example, those skilled in the art can understand that the present disclosure should not be limited thereto. In fact, the user can flexibly transform it according to the actual application scenario, as long as the reference voltage VREF and the sampling clock signal clk of the receiving circuit RX can be calibrated.

In a possible implementation, the performing calibration based on the calibration circuit in the following manner comprises: acquiring an eye diagram of the data signal DATA based on the first connection point OP and the second connection point ON; adjusting a reference voltage modulation part 4 of the calibration circuit to calibrate the reference voltage VREF, to maximize an eye width of the eye diagram; and/or adjusting a delay part 5 of the calibration circuit to calibrate the sampling clock signal clk, to enable the comparator 3 to sample a position with a maximum eye height in the eye diagram.

For example, the external signal interface chip may include a plurality of data signal line ports DQ, and each data signal line port DQ may be imparted with a separately modulated reference voltage and sampling clock signal.

When the common-mode level of the data signal DATA of a certain data signal line port DQ in the external signal interface chip deviates from the reference voltage VREF, the differential signal of the output terminal of the reference voltage modulation part 4 and the modulation amplifier 2 may be used to eliminate the common-mode deviation of the differential signal and optimize the eye width of the data signal DATA for sampling.

The delay part 5 may be configured to modulate a sampling clock signal, so that each data signal line port DQ can collect a position with a maximum eye height, to reduce a bit error rate of read data, and set edges at different times for each data signal line port DQ, to ensure that each data signal line port DQ can read data correctly, thereby improving accuracy and reliability of a function of an external signal interface chip.

The reference voltage modulation part 4 and the delay part 5 are exemplarily described below.

In the related art, the reference voltages VREF of all the data signal line ports DQ in the external signal interface chip are the same and cannot be separately modulated, in contrast, in order to reduce the bit error rate of data read by the data signal line ports DQ, in the embodiment of the present disclosure, the reference voltage modulation part 4 is provided to independently modulate the reference voltage VREF in the receiving circuit RX of each data signal line port DQ.

FIG. 5 shows a schematic circuit diagram of a reference voltage modulation part according to an embodiment of the disclosure. As shown in FIG. 5, the reference voltage modulation part 4 comprises an adjustable current source OFST_BIAS<2:0>, a first transistor M1, and a second transistor M2, a first terminal of the adjustable current source OFST_BIAS<2:0> is configured to receive a power signal, a second terminal of the adjustable current source OFST_BIAS<2:0> is connected to a first terminal of the first transistor M1 and a first terminal of the second transistor M2, a second terminal of the first transistor M1 is connected to the first connection point OP, a second terminal of the second transistor M2 is connected to the second connection point ON, a control terminal of the first transistor M1 is configured to receive a first control signal OFST_P, a control terminal of the second transistor M2 is configured to receive a second control signal OFST_N, the first control signal OFST_P and the second control signal OFST_N are configured to modulate the reference voltage VREF, and the adjustable current source OFST_BIAS<2:0> is configured to determine a modulation range of the reference voltage VREF.

The voltage at the first connection point OP is increased in response to the first transistor M1 being turned on by the first control signal OFST_P and the second transistor M2 being turned off by the second control signal OFST_N; and the voltage at the second connection point ON is increased in response to the first transistor M1 being turned off by the first control signal OFST_P and the second transistor M2 being turned on by the second control signal OFST_N.

It should be understood that the control terminals of the first transistor M1 and the second transistor M2 are gates, the first terminal may be a source, and the second terminal may be a drain; or the first terminal may be a drain, and the second terminal may be a source, which are not specifically distinguished here, and whether an NMOS (N-type transistor) or a PMOS (P-type transistor) is specifically selected may be set according to actual application scenarios. For example, whether NMOS or PMOS is selected may be determined according to the voltage range of the input data signal DATA; if the voltage range of the input data signal DATA is relatively large, NMOS may be selected; and if the voltage range of the input data signal DATA is relatively small, PMOS may be selected. Further, in a specific implementation, the NMOS is turned on under the action of a high-level signal and turned off under the action of a low-level signal. The PMOS is turned off under the action of a high-level signal and turned on under the action of a low-level signal.

For example, assuming that the power supply voltage VDDQ is 0.5 V, the voltage range of the data signal DATA is 0 to 0.5×VDDQ, the default value of the reference voltage VREF is 0.25×VDDQ, the amplifier 2 selects PMOS as the input transistor pair, and the current source of the amplifier 2 is also a PMOS current mirror, then the adjustable current source OFST_BIAS<2:0> also adopts a PMOS current source, and the first transistor M1 and the second transistor M2 adopt PMOS. The PMOS source may serve as a first terminal, and the PMOS drain may serve as a second terminal.

In this way, when the first control signal OFST_P = 0 and the second control signal OFST_N = 1, the first transistor M1 is turned on, the second transistor M2 is turned off, and the voltage at the first connection point OP increases; conversely, when the first control signal OFST_P = 1 and the second control signal OFST_N = 0, the first transistor M1 is turned off, the second transistor M2 is turned on, and the voltage at the second connection point ON increases.

Similarly, if the voltage range of the data signal DATA is greater than 0 to 0.5×VDDQ, the first transistor M1 and the second transistor M2 may adopt NMOS, wherein the drain of NMOS may serve as the first terminal, and the source of NMOS may serve as the second terminal. When the first control signal OFST_P = 1 and the second control signal OFST_N = 0, the first transistor M1 is turned on, the second transistor M2 is turned off, and the voltage at the first connection point OP increases; conversely, when the first control signal OFST_P = 0 and the second control signal OFST_N = 1, the first transistor M1 is turned off, the second transistor M2 is turned on, and the voltage at the second connection point ON increases.

It should be understood that “1” represents a high-level signal, “0” represents a low-level signal, and the high-level signal and the low-level signal are logic levels, which are only for better explaining the specific working process of the embodiments of the present disclosure, and the present disclosure does not limit the magnitude of the voltage applied to the gate of each transistor during specific implementation.

In the above process, the size of the adjustable current source OFST_BIAS<2:0> may be changed, thereby changing the modulation range of the reference voltage VREF. The larger the adjustable current source OFST_BIAS<2:0>, the larger the change of a corresponding voltage, and the smaller the adjustable current source OFST_BIAS<2:0>, the smaller the change of a corresponding voltage.

It can be seen that the reference voltage VREF is modulated by adjusting the first control signal OFST_P, the second control signal OFST_N, and the adjustable current source OFST_BIAS<2:0>, so that the comparator 2 can collect a signal with the largest eye width, thereby reducing a sampling bit error rate.

FIG. 6 shows a schematic circuit diagram of a reference voltage modulation part according to another embodiment of the present disclosure. As shown in FIG. 6, the reference voltage modulation part 4 comprises a current source OFST_BIAS, a third transistor M3, and a fourth transistor M4, a first terminal of the current source OFST_BIAS is configured to receive a power signal, a second terminal of the current source OFST_BIAS is connected to a first terminal of the third transistor M3 and a first terminal of the fourth transistor M4, a second terminal of the third transistor M3 is connected to the first connection point OP, a second terminal of the fourth transistor M4 is connected to the second connection point ON, a control terminal of the third transistor M3 is configured to receive the data signal DATA, a control terminal of the fourth transistor M4 is configured to receive the reference voltage VREF, and the reference voltage VREF is modulated by changing sizes of the third transistor M3 and the fourth transistor M4.

The control terminals of the third transistor M3 and the fourth transistor M4 are gates, the first terminal may be a source, and the second terminal may be a drain; or the first terminal may be a drain, and the second terminal may be a source, which are not specifically distinguished here, and whether an NMOS (N-type transistor) or a PMOS (P-type transistor) is specifically selected may be set according to actual application scenarios. For example, whether NMOS or PMOS is selected may be determined according to the voltage range of the input data signal DATA; if the voltage range of the input data signal DATA is relatively large, NMOS may be selected; and if the voltage range of the input data signal DATA is relatively small, PMOS may be selected.

Further, in a specific implementation, if the third transistor M3 and the fourth transistor M4 adopt NMOS, the drain of the NMOS may serve as the first terminal, the source of the NMOS may serve as the second terminal, and the NMOS is turned on under the action of a high-level signal and turned off under the action of a low-level signal. If the third transistor M3 and the fourth transistor M4 adopt PMOS, the source of the PMOS may be used as the first terminal, the drain of the PMOS may be used as the second terminal, and the PMOS is turned off under the action of a high-level signal and turned on under the action of a low-level signal.

The larger the size of the fourth transistor M4, the smaller the divided voltage current flowing through the fourth transistor M4 when the fourth transistor M4 is turned on, and the voltage at the second connection point ON increases; the smaller the size of the fourth transistor M4, the larger the divided voltage current flowing through the fourth transistor M4 when the fourth transistor M4 is turned on, and the voltage at the second connection point ON decreases.

Similarly, the larger the size of the third transistor M3, the smaller the divided current flowing through the third transistor M3 when the third transistor M3 is turned on, and the voltage at the first connection point OP increases; the smaller the size of the third transistor M3, the larger the divided current flowing through the third transistor M3 when the third transistor M3 is turned on, and the voltage at the first connection point OP decreases.

It can be seen that by adjusting the sizes of the third transistor M3 and the fourth transistor M4, the load impedance at the output terminal of the amplifier 2 can be changed, thereby modulating the reference voltage VREF, so that the comparator 2 can collect the signal with the largest eye width, and reduce the sampling bit error rate. As an example, in the chip design process, the sizes of the third transistor M3 and the fourth transistor M4 may be adjusted as needed until the eye width obtained by simulation (or oscilloscope observation) meets the requirements. The third transistor M3 and the fourth transistor M4 may also be respectively set as a plurality of transistors connected in series or in parallel, and adjusting the number of connected transistors is equivalent to adjusting the sizes of the third transistor M3 and the fourth transistor M4.

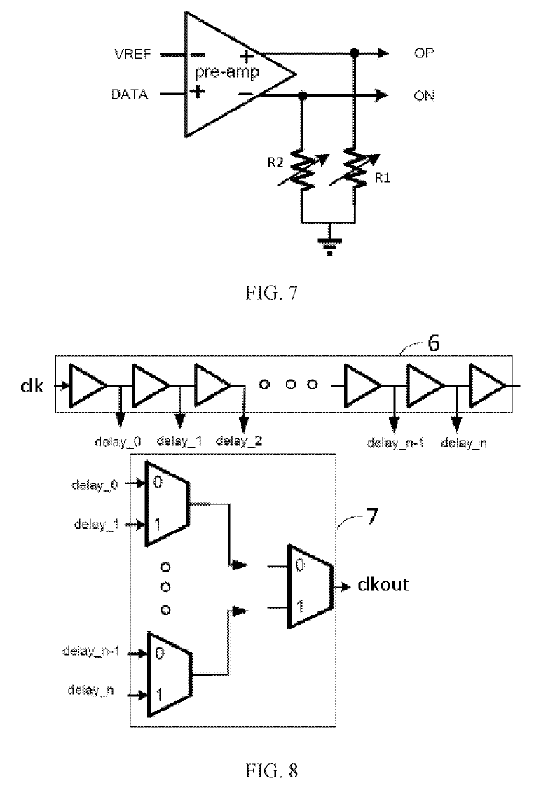

FIG. 7 shows a schematic circuit diagram of a reference voltage modulation part according to another embodiment of the present disclosure. As shown in FIG. 7, the reference voltage modulation part 4 comprises a first adjustable resistor R1 and a second adjustable resistor R2, a first terminal of the first adjustable resistor R1 is connected to the first connection point OP, a first terminal of the second adjustable resistor R2 is connected to the second connection point ON, a second terminal of the first adjustable resistor R1 and a second terminal of the second adjustable resistor R2 are grounded, and the reference voltage VREF is modulated by changing resistance values of the first adjustable resistor R1 and the second adjustable resistor R2.

The larger the resistance value of the first adjustable resistor R1, the larger the voltage obtained by the first adjustable resistor R1, and a voltage at the first connection point OP increases; and the smaller the resistance value of the first adjustable resistor R1, the smaller the voltage obtained by the first adjustable resistor R1, and a voltage at the first connection point OP decreases.

Similarly, the larger the resistance value of the second adjustable resistor R2, the larger the voltage obtained by the second adjustable resistor R2, and a voltage at the second connection point ON increases; and the smaller the resistance value of the second adjustable resistor R2, the smaller the voltage obtained by the second adjustable resistor R2, and a voltage at the second connection point ON decreases.

It can be seen that by adjusting the size of the resistance values of the first adjustable resistor R1 and the second adjustable resistor R2, the load impedance at the output terminal of the amplifier 2 can be adjusted, to modulate the reference voltage VREF, so that the comparator 2 can collect a signal with the largest eye width, thereby reducing a sampling bit error rate.

Compared with the above three solutions, the power consumption of the reference voltage modulation part 4 shown in FIG. 5 is relatively large, the accuracy is not high enough, but the modulation range of the reference voltage VREF is larger; the modulation range of the reference voltage modulation part 4 shown in FIG. 6 is relatively small, the output parasitic capacitance will become larger, the output bandwidth will be reduced, but the power consumption is low; the modulation range of the reference voltage modulation part 4 shown in FIG. 7 is relatively small, but the design is simple. In practical applications, selection may be made according to actual application scenarios.

By providing the reference voltage modulation part 4 at the output terminal of the amplifier 2, when the common-mode level of the data signal DATA deviates from the reference voltage VREF, the differential signal at the output terminal of the amplifier 2 is modulated to eliminate the common-mode deviation of the differential signal and optimize the eye width of the data signal DATA for sampling, so that the comparator 2 can collect the signal with the largest eye width and reduce the sampling bit error rate. The adjustable factors (for example, the adjustable current source OFST_BIAS<2:0>, the first control signal OFST_P, and the second control signal OFST_N in FIG. 5, the sizes of the third transistor M3 and the fourth transistor M4 in FIG. 6, and the resistance values of the first adjustable resistor R1 and the second adjustable resistor R2 in FIG. 7) in the reference voltage modulation part 4 may be adjusted by observing the eye diagrams collected at the first connection point OP and the second connection point ON, so that the eye width of the eye diagram meets the requirements.

It should be noted that although the reference voltage modulation part 4 is described above by taking FIG. 5 to FIG. 7 as an example, those skilled in the art can understand that the present disclosure should not be limited thereto. Actually, the user can flexibly transform it according to an actual application scenario.

In a possible implementation, the delay part 5 comprises a plurality of buffers sequentially connected in series and a one-out-of-multiple selector, wherein an input terminal of a first buffer in the plurality of buffers sequentially connected in series is used as the input terminal of the delay part 5 to receive the sampling clock signal clk, output terminals of the plurality of buffers are respectively connected to a plurality of input terminals of the one-out-of-multiple selector, and an output terminal of the one-out-of-multiple selector is used as the output terminal of the delay part 5 to be connected to the control terminal of the comparator 3.

Through a plurality of buffers sequentially connected in series, the sampling clock signal clk may experience different delays during transmission. Each buffer will introduce a certain delay, and after a plurality of buffers are connected in series, the total delay amount is the accumulation of the delay amount of each buffer. A function of the one-out-of-multiple selector is to select one of the outputs of a plurality of buffers as a final output, thus realizing the flexible adjustment of the delay amount. For example, if less latency is required, an output through fewer buffers is selected; if more latency is required, an output through more buffers is selected.

The sampling clock signal clk generated by the clock circuit is transmitted to each data signal line port DQ via the signal line, since the length of the signal line reaching each data signal line port DQ is different, the sampling edge of each data signal line port DQ is delayed, and since the width of the signal distinguishable by the data eye diagram decreases as the transmission rate increases, the bit error rate of reading the data signal DATA simultaneously by the plurality of data signal line ports DQ increases accordingly. Based on this, the embodiments of the present disclosure add the delay part 5 to the data signal line port DQ. The sampling clock signal clk generated by the clock circuit is input to each data signal line port DQ, modulated for different clock edges in the data signal line port DQ through buffers, and is output to the control terminal of the comparator 3, so that each comparator 3 can sample the position with the maximum eye height in the eye diagram, and in this way, the bit error rate of the data signal line port DQ reading the data signal DATA is reduced, and the bit error rate of the external signal interface chip is also reduced.

FIG. 8 shows a schematic circuit diagram of a delay part according to an embodiment of the present disclosure, as shown in FIG. 8, the delay part 5 comprises n+1 buffers 6 sequentially connected in series, and a one-out-of-multiple selector 7, the one-out-of-multiple selector 7 has n+1 input terminals, n is a positive integer, and the embodiment of the present disclosure does not limit the specific value of n.

An input terminal of a first buffer in the n+1 buffers 6 sequentially connected in series is used as an input terminal of the delay part 5 to receive the sampling clock signal clk, and output terminals of the plurality of buffers are respectively connected to a plurality of input terminals of the one-out-of-multiple selector 7, for example, an output terminal of the first buffer is connected to a first input terminal of the one-out-of-multiple selector 7 for taking the delay signal delay_0 as a candidate signal of the one-out-of-multiple selector 7; an output terminal of a second buffer is connected to a second input terminal of the one-out-of-multiple selector 7 for taking the delay signal delay_1 as a candidate signal of the one-out-of-multiple selector 7; and by analogy, an output terminal of an (n+1)th buffer is connected to an (n+1)th input terminal of the one-out-of-multiple selector 7 for taking the delay signal delay_n as a candidate signal of the one-out-of-multiple selector 7. The one-out-of-multiple selector 7 is configured to select a delayed signal from the n+1 delay signals delay_0 to delay signal delay_n as the calibrated sampling clock signal clkout and send the calibrated sampling clock signal clkout to the control terminal of the comparator 3.

The one-out-of-multiple selector 7 may comprise a plurality of one-out-of-two selectors, and the embodiments of the present disclosure do not specifically limit the circuit structure of the one-out-of-multiple selector 7. The delay times of the n+1 delay signals delay_0 to delay signal delay_n are sequentially increased, and the embodiments of the present disclosure do not limit the specific delay times.

It should be noted that although the delay part 5 is described above by taking FIG. 8 as an example, those skilled in the art can understand that the present disclosure should not be limited thereto. Actually, the user can flexibly transform it according to an actual application scenario. In application, the output of the delay part 5 and the corresponding eye diagram may be shown by an oscilloscope or the like, and the delay part 5 is adjusted when the comparator 3 controlled by the output of the delay part 5 does not sample the maximum eye height position of the eye diagram.

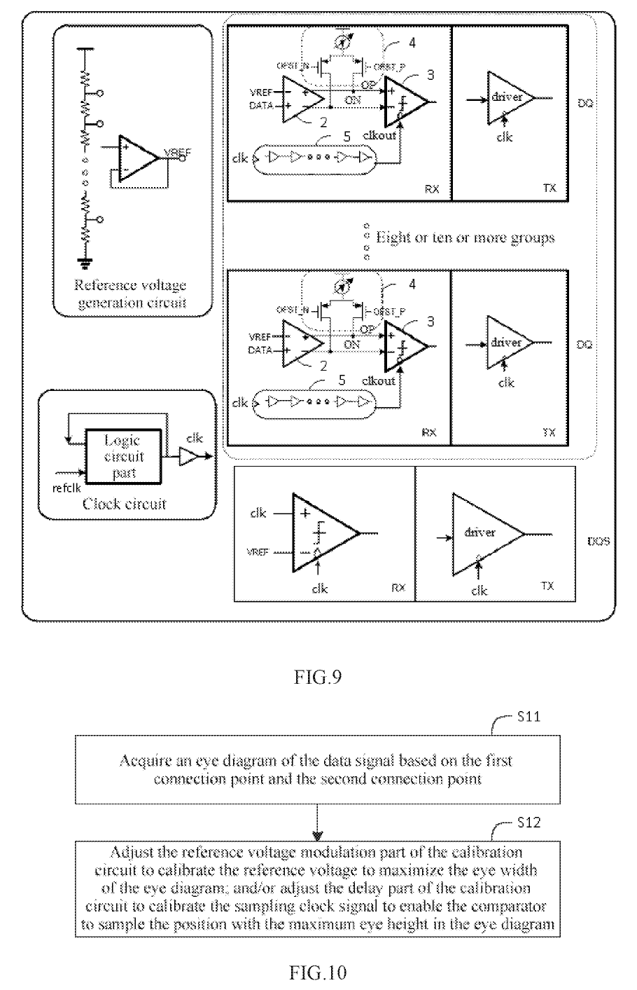

FIG. 9 shows a schematic circuit diagram of an external signal interface chip according to an embodiment of the present disclosure, as shown in FIG. 9, the external signal interface chip comprises a plurality of receiving circuits RX, the plurality of receiving circuits share the same reference voltage VREF, and each receiving circuit RX is respectively connected to one calibration circuit as described above.

It should be understood that the embodiments of the present disclosure do not specifically limit the number of receiving circuits RX, which may be set according to actual application scenarios. The reference voltage generation circuit, the clock circuit, the data signal line port DQ, and the clock signal line port DQS can be specifically referred to above, and will not be repeated here.

An independent reference voltage modulation circuit 4 may be added to each receiving circuit RX. While the plurality of receiving circuits RX share the same reference voltage VREF, each receiving circuit RX may fine-tune the respective reference voltage VREF through the independent reference voltage modulation part 4. The receiving circuit RX adopts a cascaded structure of the amplifier 2 and the comparator 3. To optimize the amplifier b, a reference voltage modulation circuit 4 that modulates a differential output signal may be added to an output terminal of the amplifier 2, to separately modulate a common-mode range of an output signal of each amplifier 2, thereby ensuring that an eye width of a data eye diagram at an input terminal of the comparator 3 in each receiving circuit RX is the largest, which is beneficial to reducing the sampling bit error rate. The implementation of the reference voltage modulation circuit 4 comprises the modulation of the size of the current source, or the size of the input transistor pair or the size of the load resistance, etc., which can be specifically referred to above, and will not be repeated here.

An independent delay part 5 may be added to each receiving circuit RX. The external signal interface chip shares the same controllable sampling clock signal clk, and the sampling clock signal clk comes from the clock circuit. The sampling clock signal clk has a deviation in time entering each receiving circuit RX due to different wiring lengths on the layout. Therefore, an independent delay part 5 is added to each receiving circuit RX, and the delay part 5 of each receiving circuit RX can finely adjust the edge of the respective sampling clock signal clk to obtain the calibrated sampling clock signal clkout, which is beneficial for each clock signal line port DQ to simultaneously read the data signal DATA as much as possible, and reduces the bit error rate of data transmission.

In this way, in the external signal interface chip of the embodiment of the present disclosure, when the read/write signal data rate supports 6400 MT/s and higher, and the plurality of clock signal line ports DQ simultaneously read random data information, the edges of the reference voltage VREF and the sampling clock signal clk for comparison in the receiving circuit RX can be separately modulated for each clock signal line port DQ, thereby improving the stability and accuracy of data transmission.

FIG. 10 shows a flowchart of a calibration method according to an embodiment of the present disclosure. As shown in FIG. 10, the method is applied to the calibration circuit as described above, and the method comprises:

in step S11, an eye diagram of the data signal is acquired based on the first connection point and the second connection point;

in step S12, the reference voltage modulation part of the calibration circuit is adjusted to calibrate the reference voltage to maximize the eye width of the eye diagram; and/or the delay part of the calibration circuit is adjusted to calibrate the sampling clock signal to enable the comparator to sample the position with the maximum eye height in the eye diagram.

In a possible implementation, the present disclosure further provides an electronic apparatus including the calibration circuit as described above.

The flowchart and block diagrams in the figures illustrate the architecture, functionality, and operation of possible implementations of systems, methods and computer program products according to various embodiments of the present disclosure. In this regard, each block in the flowchart or block diagrams may represent a part, program segment, or portion of instructions, which comprises one or more executable instructions for implementing the specified logical function. In some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart, and combinations of blocks in the block diagrams and/or flowchart, can be implemented by special purpose hardware-based systems that execute the specified functions or acts, or combinations of special purpose hardware and computer instructions.

Each embodiment of the present disclosure has been described above, and the above description is exemplary, not exhaustive, and is not limited to the disclosed each embodiment. Many modifications and changes will be obvious to those skilled in the art without departing from the scope and spirit of the illustrated each embodiment. The terminology used herein is chosen to best explain the principles of each embodiment, the practical application or technical improvement over technologies found in the marketplace, or to enable others of ordinary skill in the art to understand each embodiment disclosed herein.

What is claimed is:

1. A calibration circuit, wherein the calibration circuit is applied to an external signal interface chip, a receiving circuit of the external signal interface chip comprises an amplifier and a comparator, an inverting input terminal of the amplifier is configured to receive a reference voltage, a non-inverting input terminal of the amplifier is configured to receive an external data signal, a non-inverting output terminal of the amplifier is connected to a non-inverting input terminal of the comparator at a first connection point, and an inverting output terminal of the amplifier is connected to an inverting input terminal of the comparator at a second connection point;
the calibration circuit comprises a reference voltage modulation part and a delay part, a first terminal of the reference voltage modulation part is connected to the first connection point, a second terminal of the reference voltage modulation part is connected to the second connection point, and the reference voltage modulation part is configured to calibrate the reference voltage of the external signal interface chip;
an input terminal of the delay part is configured to receive a sampling clock signal, an output terminal of the delay part is connected to a control terminal of the comparator, and the delay part is configured to calibrate the sampling clock signal of the external signal interface chip.

2. The calibration circuit according to claim 1, wherein, based on the calibration circuit, calibration is performed as follows, comprising:
acquiring an eye diagram of the data signal based on the first connection point and the second connection point;
adjusting a reference voltage modulation part of the calibration circuit to calibrate the reference voltage to maximize an eye width of the eye diagram; and/or adjusting the delay part of the calibration circuit to calibrate the sampling clock signal to enable the comparator to sample a position with a maximum eye height in the eye diagram.

3. The calibration circuit according to claim 1, wherein the reference voltage modulation part comprises an adjustable current source, a first transistor, and a second transistor, a first terminal of the adjustable current source is configured to receive a power signal, a second terminal of the adjustable current source is connected to a first terminal of the first transistor and a first terminal of the second transistor, a second terminal of the first transistor is connected to the first connection point, a second terminal of the second transistor is connected to the second connection point, a control terminal of the first transistor is configured to receive a first control signal, a control terminal of the second transistor is configured to receive a second control signal, the first control signal and the second control signal are configured to modulate the reference voltage, and the adjustable current source is configured to determine a modulation range of the reference voltage.

4. The calibration circuit according to claim 3, wherein a voltage at the first connection point is increased in response to the first transistor being turned on by the first control signal and the second transistor being turned off by the second control signal; and
a voltage at the second connection point is increased in response to the first transistor being turned off by the first control signal and the second transistor being turned on by the second control signal.

5. The calibration circuit according to claim 1, wherein the reference voltage modulation part comprises a current source, a third transistor, and a fourth transistor, a first terminal of the current source is configured to receive a power signal, a second terminal of the current source is connected to a first terminal of the third transistor and a first terminal of the fourth transistor, a second terminal of the third transistor is connected to the first connection point, a second terminal of the fourth transistor is connected to the second connection point, a control terminal of the third transistor is configured to receive the data signal, a control terminal of the fourth transistor is configured to receive the reference voltage, and the reference voltage is modulated by changing sizes of the third transistor and the fourth transistor.

6. The calibration circuit according to claim 1, wherein the reference voltage modulation part comprises a first adjustable resistor and a second adjustable resistor, a first terminal of the first adjustable resistor is connected to the first connection point, a first terminal of the second adjustable resistor is connected to the second connection point, a second terminal of the first adjustable resistor and a second terminal of the second adjustable resistor are grounded, and the reference voltage is modulated by changing resistance values of the first adjustable resistor and the second adjustable resistor.

7. The calibration circuit according to claim 1, wherein the delay part comprises a plurality of buffers sequentially connected in series and a one-out-of-multiple selector, wherein an input terminal of a first buffer in the plurality of buffers sequentially connected in series is configured to receive the sampling clock signal as the input terminal of the delay part, output terminals of the plurality of buffers are respectively connected to a plurality of input terminals of the one-out-of-multiple selector, and an output terminal of the one-out-of-multiple selector is connected to the control terminal of the comparator as the output terminal of the delay part.

8. An external signal interface chip, wherein the external signal interface chip comprises a plurality of receiving circuits, the plurality of receiving circuits share a same reference voltage, and each receiving circuit is respectively connected to one calibration circuit,
wherein the calibration circuit is applied to the external signal interface chip, a receiving circuit of the external signal interface chip comprises an amplifier and a comparator, an inverting input terminal of the amplifier is configured to receive a reference voltage, a non-inverting input terminal of the amplifier is configured to receive an external data signal, a non-inverting output terminal of the amplifier is connected to a non-inverting input terminal of the comparator at a first connection point, and an inverting output terminal of the amplifier is connected to an inverting input terminal of the comparator at a second connection point;
the calibration circuit comprises a reference voltage modulation part and a delay part, a first terminal of the reference voltage modulation part is connected to the first connection point, a second terminal of the reference voltage modulation part is connected to the second connection point, and the reference voltage modulation part is configured to calibrate the reference voltage of the external signal interface chip;
an input terminal of the delay part is configured to receive a sampling clock signal, an output terminal of the delay part is connected to a control terminal of the comparator, and the delay part is configured to calibrate the sampling clock signal of the external signal interface chip.

9. A calibration method, wherein the method is applied to a calibration circuit,
wherein the calibration circuit is applied to an external signal interface chip, a receiving circuit of the external signal interface chip comprises an amplifier and a comparator, an inverting input terminal of the amplifier is configured to receive a reference voltage, a non-inverting input terminal of the amplifier is configured to receive an external data signal, a non-inverting output terminal of the amplifier is connected to a non-inverting input terminal of the comparator at a first connection point, and an inverting output terminal of the amplifier is connected to an inverting input terminal of the comparator at a second connection point;
the calibration circuit comprises a reference voltage modulation part and a delay part, a first terminal of the reference voltage modulation part is connected to the first connection point, a second terminal of the reference voltage modulation part is connected to the second connection point, and the reference voltage modulation part is configured to calibrate the reference voltage of the external signal interface chip;
an input terminal of the delay part is configured to receive a sampling clock signal, an output terminal of the delay part is connected to a control terminal of the comparator, and the delay part is configured to calibrate the sampling clock signal of the external signal interface chip,
the method comprising:
acquiring an eye diagram of the data signal based on the first connection point and the second connection point;
adjusting the reference voltage modulation part of the calibration circuit to calibrate the reference voltage to maximize an eye width of the eye diagram; and/or adjusting the delay part of the calibration circuit to calibrate the sampling clock signal to enable the comparator to sample a position with a maximum eye height in the eye diagram.
